(19) United States
(12) Patent Application Publication
(10) Pub. No.: US 2007/0155049 A1
(43) Pub. Date: Jul. 5, 2007

(54) Method for Manufacturing Chip Package Structures

(75) Inventor: Yu-Pin Tsai, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ADVANCED SEMICONDUCTOR ENGINEERING INC., Kaohsiung (TW)

(21) Appl. No.: 11/559,036

(22) Filed: Nov. 13, 2006

(30) Foreign Application Priority Data
Dec. 30, 2005 (TW) 94147807

(51) Int. Cl. H01L 21/00

(52) U.S. Cl. 438/106; 438/113; 438/613

(57) ABSTRACT

A wafer-level method for manufacturing a chip package structure is disclosed. A wafer comprises a first surface and a second surface opposite thereto. The first surface has chip units disposed thereon to define scribe lines. An adhesive material is disposed between the first surface and the transparent glass for adhering the wafer to a transparent glass and leaving no gap between the first surface and the transparent glass. The wafer is vertically cut from the second surface corresponding to each scribe line of the first surface to the encapsulation adhesive material for forming scribe grooves, and then the second surface is coated with an encapsulation material for filling the scribe grooves. After removing the adhesive material and the transparent glass, the encapsulation material in each of the scribe grooves is vertically cut from the first surface, so as to form chip package structures.

### RELATED APPLICATIONS

The present application is based on, and claims priority from, Taiwan Application Serial Number 94147807, filed Dec. 30, 2005, the disclosure of which is hereby incorporated by reference herein in its entirety.

### FIELD OF THE INVENTION

This invention relates generally to a method for manufacturing chip-scale package (CSP) structures, and more particularly, to a wafer-level method for manufacturing a plurality of CSP structures.

### BACKGROUND OF THE INVENTION

As the demand for lighter and more complicated electronic devices is increasing, the speed and complication of the chip is relatively higher as well, there is a need for higher packaging efficiency to satisfy the requirement for packaging chips. Miniaturization is a major driving force to apply the advanced packaging technology, for example, CSP and flip chip. Comparison with the ball grid array (BGA) or thin small outline package (TSOP), the two techniques, CSP and flip chip, both substantially raise the packaging efficiency, thereby reducing the required substrate space. Typically, CSP is equal to or slightly larger than the chip itself in size (the maximum of approximately 20 percent). In addition, CSP can directly promote the tests of known good die (KGD) and burn-in. Moreover, CSP also can combine the advantages of standardization and reprocessing in the surface mount technology (SMT), low impedance of flip chip, high I/O pins and directly heat dissipating path and so forth, so as to enhance the efficiency of CSP.

However, comparison with BGA or TSOP, CSP has a disadvantage of higher production cost. If CSP could be produced in large scale, the aforementioned disadvantages will be overcome. Hence, the manufacturers of chip packages attempt to develop novel wafer-level packaging technologies, so as to produce CSP structures in large scale. In the development field of wafer-level packaging technology, the backside wafer coating is a just starting process. However, in the backside wafer coating technique, the encapsulation cannot be dried quickly after coating, resulting in more complicated process and higher production cost. In addition, after completion of the molding procedure, some residual stress existing in the molded chip induces the chip to warp easily.

### SUMMARY OF THE INVENTION

Accordingly, there is an urgent need to provide an improved wafer-level method for manufacturing a plurality of CSP structures, for solving the aforementioned problems of more complicated, more time-consuming, and higher-cost process existed in the prior art, so as to achieve the purpose of simplified, time-saving, and low-cost process.

An aspect of the present invention provides a wafer-level method for manufacturing a plurality of CSP structures, which cuts a wafer backside to form a plurality of scribe grooves for containing an encapsulation material coated on the wafer backside, so as to quickly dry the encapsulation material and to prevent the molded wafer from warping.

According to the aforementioned aspect of the present invention, the wafer-level method for manufacturing a plurality of CSP structures of a preferred embodiment of the present invention comprises the steps. A wafer is provided, which comprises a first surface and a second surface opposite to the first surface, wherein the first surface has a plurality of chip units disposed thereon to define a plurality of scribe lines, and the chip units have a plurality of conductive bumps formed thereon. An adhesive material is provided for adhering the wafer to a transparent glass, wherein the adhesive material is disposed between the first surface and the transparent glass, and the adhesive material substantially covers the conductive bumps, so as to leave no gap between the first surface and the transparent glass. The wafer is vertically cut from the second surface corresponding to each scribe line of the first surface to the adhesive material, so as to form a plurality of scribe grooves. A molding procedure is performed to coat the second surface with an encapsulation material, wherein the encapsulation material fills the scribe grooves; removing the adhesive material and the transparent glass; and vertically cutting the encapsulation material in each of the scribe grooves from the first surface, so as to form a plurality of chip package structures.

In another preferred embodiment of the present invention, the aforementioned conductive bumps may be, for example, solder balls.

With application to the aforementioned wafer-level method for manufacturing a plurality of CSP structures, the wafer backside is firstly cut to form a plurality of scribe grooves for containing the encapsulation material that is coated on the wafer backside, so as to quickly dry the encapsulation material and to prevent the encapsulated wafer from warping. Moreover, with application to the aforementioned structure for packaging a chip, the encapsulation material is disposed on the backside and four sides of the wafer, in addition to the inherent passivation layer of the wafer front side, for preventing moisture or light from penetrating the wafer, as well as protecting an edge or corner of the wafer from suffering edge chipping or other defects. Hence, in comparison with the prior packaging process and structure, the method of the present invention is relatively simplified, and the process time and cost are substantially reduced. Besides, the package structure of the present invention has better efficacy of preventing moisture or light from penetrating the wafer, as well as protecting an edge or corner of the wafer from suffering defects.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional diagram of a CSP structure according to one preferred embodiment of the present invention; and

FIGS. 2A to 2D are cross-sectional flow diagrams showing another embodiment according to a wafer-level method for manufacturing a plurality of CSP structures.

### DETAILED DESCRIPTION OF THE PREFERRED EMBODIMENT

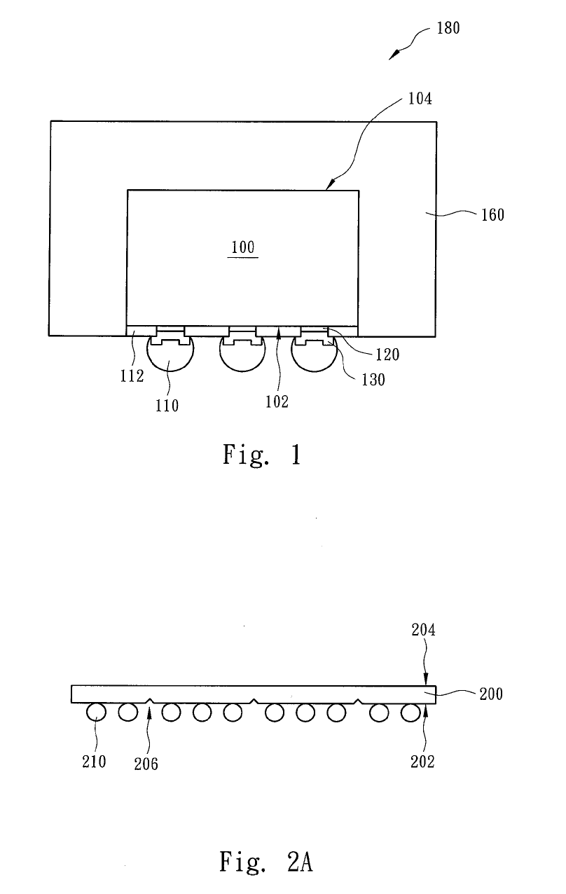

Reference is made to FIG. 1, which depicts a cross-sectional diagram of a CSP structure according to one preferred embodiment of the present invention. The CSP structure 180 comprises a chip 100 and an encapsulation 160, wherein the chip 100 comprises a first surface 102 and a second surface 104 opposite to the first surface 102 thereon. In this embodiment, the first surface 102 may be an active surface, and on which a passivation layer 112 and a plurality of conductive bumps such as solder balls 100 are disposed. The passivation layer 112 covers a part of the first surface 102 to expose the solder balls 110 that server as input/output (I/O) electrodes of the wafer 100. The encapsulation 160 is disposed on the second surface 104 and four sides of the wafer 100. It should be comprehended that, a plurality of pads 120 and under bump metallurgy (UBM) layers 130 are further comprised between the first surface 102 and the solder balls 110, which assist the chip 100 in electrically connecting to the solder balls 110, wherein the pads 120 are disposed between the first surface 102 and the solder balls 110, and the UBM layers 130 are disposed between the pads 120 and the solder balls 110. In this embodiment, the passivation layer 112 is preferably formed from a material of polyimide (PI) or benzocyclobutene (BCB), and the encapsulation 160 is preferably formed from a material of epoxy resin. Since the encapsulation 160 is completely coated on the second surface 104 and four sides of the wafer 100, in addition to the passivation layer (not shown) disposed on the first surface 102 of the wafer 100, the whole wafer 100 is subjected to complete protection for preventing moisture or light from penetrating the wafer 100, and for protecting an edge or corner of the wafer 100 from suffering edge chipping, peeling off or other defects. Thus, it results in increased packaging yield of the CSP structure 180. Furthermore, the encapsulation 160 can also be marked thereon by applying laser engraving or other methods, so as to identify the CSP structure 180.

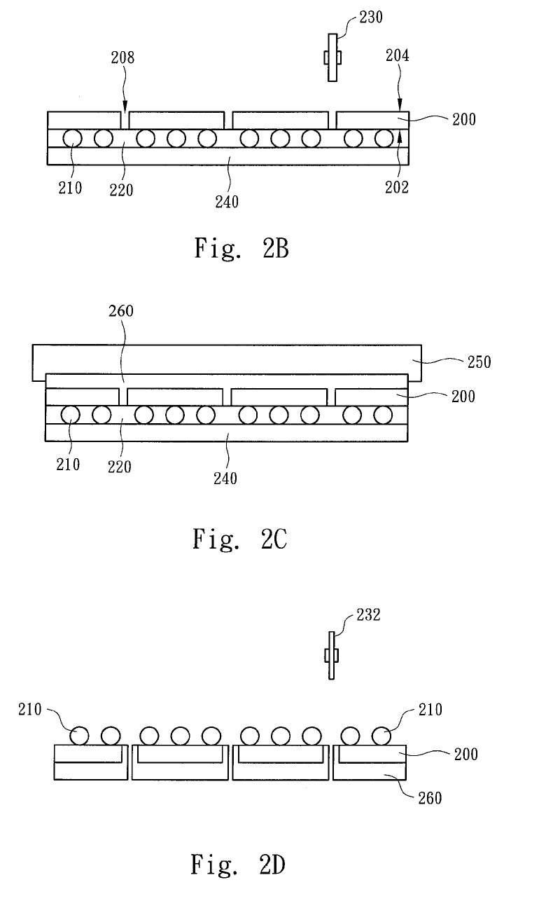

Reference is made to FIGS. 2A to 2D, which depict cross-sectional flow diagrams showing another embodiment according to a wafer-level method for manufacturing a plurality of CSP structures. As firstly shown in FIG. 2A, a wafer 200 is provided, which comprises a first surface 202 and a second surface 204 opposite to the first surface 202. In this embodiment, the first surface 202 has a plurality of conductive bumps (e.g. solder balls 210) and a passivation layer (not shown) disposed thereon. It is worth mentioning that, the first surface 202 further has a plurality of pads (not shown) and UBM layers (not shown) disposed thereon, so as to assist the wafer 200 in electrically connecting to the solder balls 210. In addition, the first surface 202 has a plurality of scribe lines 206 formed thereon, for defining a plurality of chip units on the wafer 200.

Next, as shown in FIG. 2B, an adhesive material 220 is provided for adhering the wafer 200 to a transparent glass 240, wherein the adhesive material 220 is disposed between the first surface 202 of the wafer 200 and the transparent glass 240, and the adhesive material 220 substantially covers the solder balls 210, so as to leave no gap between the first surface 202 of the wafer 200 and the transparent glass 240. In this embodiment, the adhesive material 220 has a transmittance substantially more than 70%, so as to carry out an optical positioning procedure. The adhesive material 220 is made of a heat-resistant material, and it can resist heat under a processing environment of 200° C. for 30 minutes, so as to be capable of keeping its shape and viscosity during the subsequently molding procedure. Besides, in this embodiment, the adhesive material 220 adheres the wafer 200 to a transparent glass 240 through the following steps. The adhesive material 220 firstly pre-adheres to the transparent glass 240 by using a lamination procedure. And then, the wafer 200 adheres to the transparent glass 240 covered with the adhesive material 220 by using a vacuum pressure. Afterward, the wafer 200 is vertically cut from the second surface 204 corresponding to each scribe line 206 of the first surface 202 to the adhesive material 220 by using a first dicing blade 230, so as to form a plurality of scribe grooves 208. It is could be comprehended that, the wafer 200 is actually separated into a plurality of chips, however, the original shape of the wafer 200 can still be maintained in support of the adhesive material 220 and the transparent glass 240.

And then, as shown in FIG. 2C, a molding procedure is performed to coat the second surface 204 of the wafer 200 with an encapsulation material, for example, epoxy resin. In this embodiment, the wafer is put into a mold cavity 250 of a molding machine (not shown), and the encapsulation material, such as a molding compound 260, is put between the second surface 204 of the wafer 200 and the mold cavity 250. Next, the mold cavity 250 is employed to heat and press the molding compound 260, so as to cover the second surface 204 of the wafer 200 with the molding compound 260. At this time, the molding compound 260 also fills the scribe grooves 208. In this embodiment, the molding compound 260 is cured by way of heating and pressing. However, other molding methods can be applied in the present invention but not limited by the above description. It is worth mentioning that, the separation of the adhesive material 220, in addition to the support of the transparent glass 240, prevent the molding compound 260 from molding flash on the first surface 202 of the wafer 200. Since the scribe grooves 208 not only contain the molding compound 260 coated on the second surface (i.e. backside) of the wafer, but also prevent the chips from warping after quickly drying or curing the molding compound 260.

Subsequently, as shown in FIG. 2D, the adhesive material 220 and the transparent glass 240 are removed. Afterward, the molding compound 260 in the each scribe groove 208 is vertically cut from the first surface 202, using a second dicing blade 232, so as to form CSP structures 180 as shown in FIG. 1. In this embodiment, a conventional wafer dicing method is applied in the cutting step, which firstly adheres the molding compound 260 of the second surface 204 of the wafer 200 to a sticky sheet (not shown), for example, a blue tape utilized in wafer dicing, and supports it by using an annular frame (not shown). Next, the molding compound 260 in the each scribe groove 208 is vertically cut from the first surface 202 by using the second dicing blade 232. It can be understood that the second dicing blade 232 is thinner than the first dicing blade 230 that is utilized for forming scribe grooves 208.

In brief, the wafer-level method for manufacturing a plurality of CSP structures is characterized by firstly cutting the wafer backside to form a plurality of scribe grooves for containing the encapsulation material. Since the wafer is actually separated into a plurality of chips, the encapsulation material on the backside and four sides of the wafer can be quickly dried or cured, instead of the prior problem of wafer warping after the molding procedure. Therefore, the present invention overcomes the disadvantage that the encapsulation material is warped on the wafer backside. In addition, the CSP structure of the present invention has the encapsulation material disposed on the backside and four sides of the wafer, so it can prevent moisture or light from penetrating the wafer, and protect an edge or corner of the wafer from suffering edge chipping, peeling off or other defects. Besides, the encapsulation material on the wafer backside can further be marked thereon, so as to identify the CSP structure. Hence, in comparison with the prior packaging process and structure, the method of the present invention is relatively simplified, and the process time and cost are substantially reduced. Additionally, the package structure of the present invention has better efficacy of preventing moisture or light from penetrating the wafer, as well as protecting an edge or corner of the wafer from suffering defects.

Therefore, according to the aforementioned preferred embodiments, one advantage of the wafer-level method for manufacturing a plurality of CSP structures of the present invention is that, during the molding procedure, there is no demand for complicated and long process, and consumption of time and cost as well. The shape of the wafer can be maintained merely in support of the adhesive material and the transparent glass, and the encapsulation material is coated on the backside and four sides of the wafer. It results that the encapsulation material is quickly dried or cured, instead of the prior problem of wafer warping after the molding procedure. Consequently, the wafer-level method for manufacturing a plurality of CSP structures of the present invention not only simplifies the prior packaging process of CSP structures, but also substantially reduces the process time and cost.

As is understood by a person skilled in the art, the foregoing preferred embodiments of the present invention are illustrated of the present invention rather than limiting of the present invention. It is intended to cover various modifications and similar arrangements included within the spirit and scope of the appended claims. Therefore, the scope of which should be accorded the broadest interpretation so as to encompass all such modifications and similar structure.

What is claimed is:

1. A method for manufacturing a chip package structure, comprising:
providing a wafer that comprises a first surface and a second surface opposite to the first surface, wherein the first surface has a plurality of chip units disposed thereon to define a plurality of scribe lines, and the chip units have a plurality of conductive bumps formed thereon;
providing an adhesive material for adhering the wafer to a transparent glass, wherein the adhesive material is disposed between the first surface and the transparent glass, and the adhesive material substantially covers the conductive bumps, so as to leave no gap between the first surface and the transparent glass;
vertically cutting the wafer from the second surface corresponding to each scribe line of the first surface to the adhesive material, so as to form a plurality of cutting lanes;
performing a molding procedure to coat the second surface with an encapsulation material, wherein the encapsulation material fills the cutting lanes;
removing the adhesive material and the transparent glass; and
vertically cutting the encapsulation material in each of the cutting lanes from the first surface, so as to form a plurality of chip package structures.

2. The method for manufacturing the chip package structure according to claim 1, wherein the conductive bumps are solder balls.

3. The method for manufacturing the chip package structure according to claim 1, wherein the adhesive material has a transmittance substantially more than 70%.

4. The method for manufacturing the chip package structure according to claim 1, wherein the adhesive material is made of a heat-resistant material for keeping a shape and viscosity of the adhesive material during the molding procedure.

5. The method for manufacturing the chip package structure according to claim 1, wherein the step of providing the adhesive material further comprises:
pre-adhering the adhesive material to the transparent glass, so as to form a transparent glass covered with the adhesive material.

6. The method for manufacturing the chip package structure according to claim 5, wherein the adhesive material is pre-adhered to the transparent glass by using a lamination procedure.

7. The method for manufacturing the chip package structure according to claim 1, wherein the step of adhering the wafer to the transparent glass further comprises:
providing a transparent glass covered with the adhesive material; and
adhering the wafer to the transparent glass covered with the adhesive material.

8. The method for manufacturing the chip package structure according to claim 7, wherein the wafer is adhered to the transparent glass covered with the adhesive material by using a vacuum pressure.

9. The method for manufacturing the chip package structure according to claim 1, wherein the molding procedure comprises steps of heating and pressing the encapsulation material.

10. The method for manufacturing the chip package structure according to claim 1, wherein the molding procedure comprises a step of drying or curing the encapsulation material.

11. The method for manufacturing the chip package structure according to claim 1, wherein the encapsulation material is a material of epoxy resin.

12. The method for manufacturing the chip package structure according to claim 1, wherein the cutting lanes are formed by using a first dicing blade, and the chip package structures are formed by a second dicing blade, and wherein the second dicing blade is thinner than the first dicing blade.

13. The method for manufacturing the chip package structure according to claim 1, wherein the encapsulation material is coated on the second surface and four sides of the chip of the chip package structure.

14. The method for manufacturing the chip package structure according to claim 1, wherein the step of forming the conductive bumps further comprises:
forming a plurality of pads between the first surface and the conductive bumps for electrically connecting the chip to the conductive bumps.

15. The method for manufacturing the chip package structure according to claim 14, wherein the step of forming the pads further comprises:
forming a plurality of under bump metallurgy (UBM) layers between the pads and the conductive bumps for electrically connecting the chip and the pads to the conductive bumps.

16. The method for manufacturing the chip package structure according to claim 1, wherein the step of forming the conductive bumps further comprises:
forming a passivation layer on the first surface, wherein the passivation layer exposes the conductive bumps.

17. The method for manufacturing the chip package structure according to claim 16, wherein the passivation layer is a material of polyimide (PI) or benzocyclobutene (BCB).
